(19) United States
(12) Patent Application Publication
(10) Pub. No.: US 2012/0204943 A1
(43) Pub. Date: Aug. 16, 2012

(54) Hybrid Solar Cell and Method for Manufacturing the Same

(76) Inventor: Jin Hyuk Yoo, Seongnam-si (KR)

(21) Appl. No.: 13/502,731

(22) PCT Filed: Jan. 1, 2010
(86) PCT No.: PCT/KR10/00002

§ 371 Date: Apr. 18, 2012

(30) Foreign Application Priority Data
Oct. 21, 2009 (KR) 10-2009-0100126

(51) Int. Cl. H01L 31/0352; H01L 31/0224

(52) U.S. Cl. 136/255; 438/87; 438/98; 257/E31.124

(57) ABSTRACT

A hybrid solar cell is disclosed, which is capable of preventing a defect from occurring in a surface of a semiconductor wafer when forming a thin-film type semiconductor layer on the semiconductor wafer, to thereby improve cell efficiency by the increase of open-circuit voltage, the hybrid solar cell comprising a semiconductor wafer having a predetermined polarity; a first semiconductor layer on one surface of the semiconductor wafer; a second semiconductor layer on the other surface of the semiconductor wafer, wherein the second semiconductor layer is different in polarity from the first semiconductor layer; a first electrode on the first semiconductor layer; and a second electrode on the second semiconductor layer; wherein the first semiconductor layer comprises a lightly doped first semiconductor layer on one surface of the semiconductor wafer; and a highly doped first semiconductor layer on the lightly doped first semiconductor layer.

### CROSS REFERENCE TO RELATED APPLICATIONS

This application claims the benefit of the Korean Patent Application No. P2009-0100126 filed on Oct. 21, 2009, which is hereby incorporated by reference as if fully set forth herein.

### BACKGROUND OF THE INVENTION

1. Field of the Invention

The present invention relates to a solar cell, and more particularly, to a hybrid solar cell.

2. Discussion of the Related Art

A solar cell with a property of semiconductor converts a light energy into an electric energy.

The solar cell is formed in a PN junction structure where a positive (P)-type semiconductor makes a junction with a negative (N)-type semiconductor. When solar ray is incident on the solar cell with the PN junction structure, holes (+) and electrons (−) are generated in the semiconductor owing to the energy of the solar ray. By an electric field generated in the PN junction, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. The thin film type solar cell is advantageous in that its manufacturing cost is relatively lower than that of the wafer type solar cell.

There has been proposed a hybrid solar cell obtained by combining the wafer type solar cell and the thin film type solar cell, which will be explained as follows with reference to the accompanying drawings.

FIG. 1 is a cross section view illustrating a related art hybrid solar cell.

As shown in FIG. 1, the related art hybrid solar cell includes a semiconductor wafer 10, a first semiconductor layer 20, a first electrode 30, a second semiconductor layer 40, and a second electrode 50.

The first semiconductor layer 20 is formed in a thin-film type on an upper surface of the semiconductor wafer 10; and the second semiconductor layer 40 is formed in a thin-film type on a lower surface of the semiconductor wafer 10. Thus, a PN junction structure can be made by combining the semiconductor wafer 10, the first semiconductor layer 20, and the second semiconductor layer 40.

The first electrode 30 is formed on the first semiconductor layer 20, and the second electrode 50 is formed on the second semiconductor layer 40, whereby the first and second electrodes 30 and 50 respectively serve as (+) and (−) polarities of the solar cell.

However, the related art hybrid solar cell has the following disadvantages.

During the process for forming the first or second semiconductor layer 20 or 40 in the related art hybrid solar cell, a defect may occur in the surface of the semiconductor wafer 10.

That is, the first or second semiconductor layer 20 or 40 is formed on the upper or lower surface of the semiconductor wafer 10, wherein the first and second semiconductor layers 20 and 40 are doped by using a predetermined dopant gas. At this time, the defect may occur in the upper or lower surface of the semiconductor wafer 10 due to the dopant gas, whereby the cell efficiency is lowered by the decrease of open-circuit voltage.

### SUMMARY OF THE INVENTION

Accordingly, the present invention is directed to a hybrid solar cell and a method for manufacturing the same that substantially obviates one or more problems due to limitations and disadvantages of the related art.

An object of the present invention is to provide a hybrid solar cell and a method for manufacturing the same, which is capable of preventing a defect from occurring in a surface of a semiconductor wafer when forming a thin-film type semiconductor layer on the semiconductor wafer, to thereby improve cell efficiency by the increase of open-circuit voltage.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a hybrid solar cell comprising a semiconductor wafer having a predetermined polarity; a first semiconductor layer on one surface of the semiconductor wafer; a second semiconductor layer on the other surface of the semiconductor wafer, wherein the second semiconductor layer is different in polarity from the first semiconductor layer; a first electrode on the first semiconductor layer; and a second electrode on the second semiconductor layer; wherein the first semiconductor layer comprises a lightly doped first semiconductor layer on one surface of the semiconductor wafer, and a highly doped first semiconductor layer on the lightly doped first semiconductor layer.

In another aspect of the present invention, a method for manufacturing a hybrid solar cell comprises forming a first semiconductor layer on one surface of a semiconductor wafer having a predetermined polarity; forming a second semiconductor layer on the other surface of the semiconductor wafer, wherein the second semiconductor layer is different in polarity from the first semiconductor layer; forming a first electrode on the first semiconductor layer; and forming a second electrode on the second semiconductor layer; wherein the process for forming the first semiconductor layer comprises forming a lightly doped first semiconductor layer on one surface of the semiconductor wafer, and forming a highly doped first semiconductor layer on the lightly doped first semiconductor layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view illustrating a related art hybrid solar cell;

FIG. 2 is a cross section view illustrating a hybrid solar cell according to one embodiment of the present invention; and

FIG. 3(A to F) is a series of cross section views illustrating a method for manufacturing a hybrid solar cell according to one embodiment of the present invention.

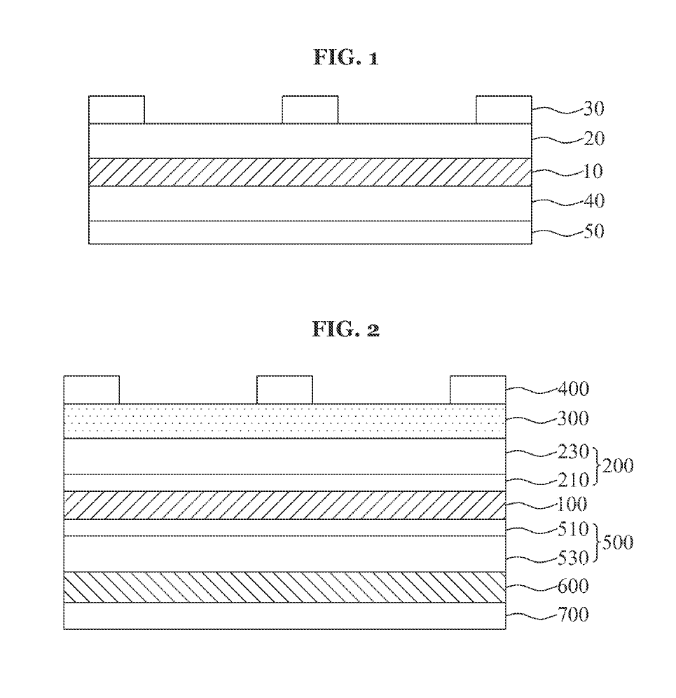

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a hybrid solar cell according to one embodiment of the present invention will be described with reference to the accompanying drawings.

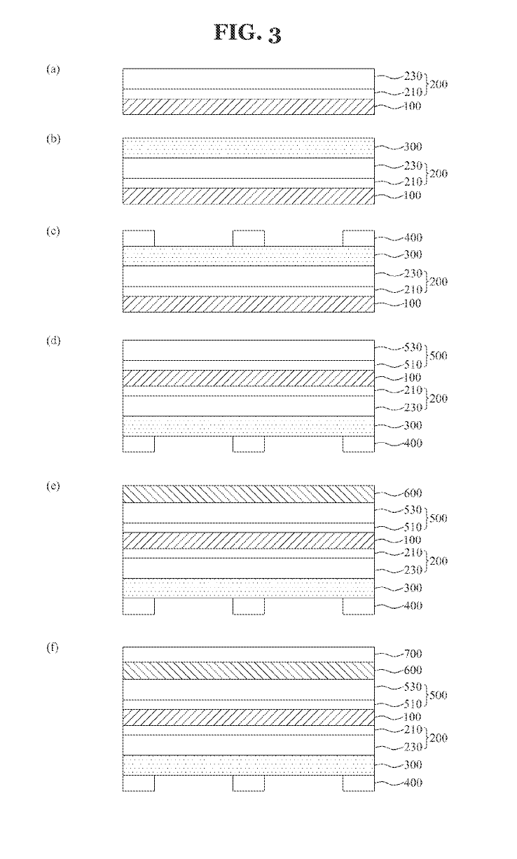

FIG. 2 is a cross section view illustrating a hybrid solar cell according to one embodiment of the present invention.

As shown in FIG. 2, the hybrid solar cell according to one embodiment of the present invention includes a semiconductor wafer 100, a first semiconductor layer 200, a first transparent conductive layer 300, a first electrode 400, a second semiconductor layer 500, a second transparent conductive layer 600, and a second electrode 700.

The semiconductor wafer 100 may be formed of a silicon wafer, and more particularly, an N-type silicon wafer. The semiconductor wafer 100 may be formed of a P-type silicon wafer.

The first semiconductor layer 200 is formed in a thin-film type on an upper surface of the semiconductor wafer 100. The first semiconductor layer 200 can make a PN junction with the semiconductor wafer 100. Thus, if the semiconductor wafer 100 is formed of the N-type silicon wafer, the first semiconductor layer 200 may be formed of a P-type semiconductor layer. Especially, the first semiconductor layer 200 may be formed of P-type amorphous silicon doped with a group III element in the periodic table, for example, boron (B).

The first semiconductor layer 200 may comprise a lightly doped P-type semiconductor layer 210 and a highly doped P-type semiconductor layer 230, wherein the lightly doped P-type semiconductor layer 210 is formed on the upper surface of the semiconductor wafer 100, and the highly doped P-type semiconductor layer 230 is formed on the lightly doped P-type semiconductor layer 210. Herein, the lightly or highly doped layers are relative concepts. This indicates that a doping concentration of group III element of the periodic table in the lightly doped P-type semiconductor layer 210 is relatively lower than a doping concentration of group III element of the periodic table in the highly doped P-type semiconductor layer 230.

The lightly doped P-type semiconductor layer 210 enhances the interfacial property between the semiconductor wafer 100 and the highly doped P-type semiconductor layer 230. This will be explained in detail. A doping gas may cause a defect in a surface of the semiconductor wafer 100. As shown in the hybrid solar cell according to the present invention, when the lightly doped P-type semiconductor layer 210 is firstly formed on the semiconductor wafer 100, and then the highly doped P-type semiconductor layer 230 is formed on the lightly doped P-type semiconductor layer 210, it is possible to prevent the defect from occurring in the surface of the semiconductor wafer 100, thereby improving the cell efficiency by the increase of open-circuit voltage. Preferably, the doping concentration in the lightly doped P-type semiconductor layer 210 is regulated to have such level as to prevent the occurrence of defect in the surface of the semiconductor wafer 100.

If an I(intrinsic)-type semiconductor layer is formed between the semiconductor wafer 100 and the highly doped P-type semiconductor layer 230, it is possible to prevent the defect in the surface of the semiconductor wafer 100, the defect caused by the doping gas. However, since a process for forming the I-type semiconductor layer has to be additionally carried out, it requires an additional deposition apparatus, thereby lowering the yield due to the complicated process. According to the present invention, both the lightly doped P-type semiconductor layer 210 and the highly doped P-type semiconductor layer 230 are sequentially formed in one chamber, whereby it is possible to prevent the occurrence of defect in the surface of the semiconductor wafer 100 without an additional apparatus and process.

The first transparent conductive layer 300 is formed on the first semiconductor layer 200, wherein the first transparent conductive layer 300 collects carriers. The first transparent conductive layer 300 may be omissible. For a smooth drift of the carriers from the first semiconductor layer 200 to the first electrode 400, forming the first transparent conductive layer 300 is preferable to omitting the first transparent conductive layer 300.

The first transparent conductive layer 300 may be formed of a transparent conductive material, for example, ZnO:B, ZnO:Al, SnO₂, SnO₂:F, or ITO (Indium Tin Oxide).

The first electrode 400 is formed on the first transparent conductive layer 300. Preferably, the plurality of first electrodes 400 are formed at fixed intervals so that solar ray can be transmitted to the inside of the solar cell through the interval between each first electrode 400. This is because the first electrode 400 is positioned at the most frontal portion of the solar cell. If using an opaque metal material for each first electrode 400, the plurality of first electrodes 400 are patterned at fixed intervals so that the solar ray can be transmitted to the inside of the solar cell through the interval between each first electrode 400.

The first electrode 400 may be formed of a metal material, for example, Ag, Al, Ag+Al, Ag+Mg, Ag+Mn, Ag+Sb, Ag+Zn, Ag+Mo, Ag+Ni, Ag+Cu, or Ag+Al+Zn.

The second semiconductor layer 500 is formed in a thin-film type on a lower surface of the semiconductor wafer 100. The second semiconductor layer 500 is different in polarity from the first semiconductor layer 200. If the first semiconductor layer 200 is formed of the P-type semiconductor layer doped with the group III element in the periodic table, for example, boron (B); the second semiconductor layer 500 may be formed of the N-type semiconductor layer doped with a group V element in the periodic table, for example, phosphorous (P). Especially, the second semiconductor layer 500 may be formed of N-type amorphous silicon.

The second semiconductor layer 500 may comprise a lightly doped N-type semiconductor layer 510 and a highly doped N-type semiconductor layer 530, wherein the lightly doped N-type semiconductor layer 510 is formed on the lower surface of the semiconductor wafer 100, and the highly doped N-type semiconductor layer 530 is formed on the lightly doped N-type semiconductor layer 510.

The lightly doped N-type semiconductor layer 510 is similar in function to the lightly doped P-type semiconductor layer 210. That is, the lightly doped N-type semiconductor layer 510 prevents occurrence of the defect in the surface of the semiconductor wafer 100, the defect caused by the doping gas. Thus, a doping concentration in the lightly doped N-type semiconductor layer 510 is regulated to have such level as to prevent the occurrence of defect in the surface of the semiconductor wafer 100, preferably. Like the aforementioned P-type semiconductor layers 210 and 230, both the lightly doped N-type semiconductor layer 510 and the highly doped N-type semiconductor layer 530 are sequentially formed in one chamber, whereby it is possible to prevent the occurrence of defect in the surface of the semiconductor wafer 100 without an additional apparatus and process.

The second transparent conductive layer 600 is formed on the second semiconductor layer 500, wherein the second transparent conductive layer 600 collects carriers. Like the aforementioned first transparent conductive layer 300, the second transparent conductive layer 600 may be omissible. For a smooth drift of the carriers from the second semiconductor layer 500 to the second electrode 700, forming the second transparent conductive layer 600 is preferable to omitting the second transparent conductive layer 600.

The second transparent conductive layer 600 may be formed of the same material as that of the first transparent conductive layer 300. For example, the second transparent conductive layer 600 may be formed of a transparent conductive material such as ZnO:B, ZnO:Al, SnO₂, SnO₂:F, or ITO (Indium Tin Oxide).

The second electrode 700 is formed on the second transparent conductive layer 600. The second electrode 700 is positioned at the most rear portion of the solar cell. That is, even though each second electrode 700 is formed of the opaque metal material, there is no need to form the plurality of second electrodes 700 at fixed intervals. Thus, the second electrode 700 may be formed on an entire surface of the second transparent conductive layer 600.

The second electrode 700 may be formed of the same material as that of the first electrode 400, for example, the metal material such as Ag, Al, Ag+Al, Ag+Mg, Ag+Mn, Ag+Sb, Ag+Zn, Ag+Mo, Ag+Ni, Ag+Cu, or Ag+Al+Zn.

FIG. 3(A to F) is a series of cross section views illustrating a method for manufacturing the hybrid solar cell according to one embodiment of the present invention.

First, as shown in FIG. 3(A), the first semiconductor layer 200 is formed on the semiconductor wafer 100.

The semiconductor wafer 100 may be formed of the N-type silicon wafer.

A process for forming the first semiconductor layer 200 may comprise forming the P-type semiconductor layer, for example, the P-type amorphous silicon layer on the semiconductor wafer 100 by PECVD (Plasma Enhanced Chemical Vapor Deposition).

Another process for forming the first semiconductor layer 200 may comprise forming the lightly doped P-type semiconductor layer 210 on the semiconductor wafer 100; and forming the highly doped P-type semiconductor layer 230 on the lightly doped P-type semiconductor layer 210.

Both the lightly doped P-type semiconductor layer 210 and the highly doped P-type semiconductor layer 230 may be sequentially formed in one chamber. That is, the lightly doped P-type semiconductor layer 210 and the highly doped P-type semiconductor layer 230 may be formed sequentially by regulating a supplying amount of dopant gas of group III element of the periodic table, for example, boron (B) in a PECVD (Plasma Enhanced Chemical Vapor Deposition) chamber.

For manufacturing an initial solar cell in mass production, the P-type dopant atmosphere is created inside the chamber by supplying a predetermined amount of B₂H₆ gas to the inside of the chamber, and then SiH₄ and H₂ gases are supplied to the inside of the chamber, to thereby form the lightly doped P-type semiconductor layer 210, and more particularly, the lightly doped P-type amorphous silicon layer. Thereafter, when supplying SiH₄ and H₂ gases, B₂H₆ gas serving as the dopant gas is additionally supplied to the inside of the chamber, thereby forming the highly doped P-type semiconductor layer 230, and more particularly, the highly doped P-type amorphous silicon layer.

After completing the process for forming the highly doped P-type semiconductor layer 230, some of B₂H₆ gas may remain in the chamber. From the process for manufacturing the following solar cells after the initial solar cell, the inside of the chamber is already prepared with the P-type dopant atmosphere. Thus, only SiH₄ and H₂ gases are supplied to the inside of the chamber without supplying B₂H₆ gas to the inside of the chamber, to thereby form the lightly doped P-type semiconductor layer 210. Thereafter, when supplying SiH₄ and H₂ gases, B₂H₆ gas serving as the dopant gas is additionally supplied to the inside of the chamber, thereby forming the highly doped P-type semiconductor layer 230.

However, it is not limited to the aforementioned method. After manufacturing the initial solar cell, the chamber may be supplied with a very small amount of B₂H₆ gas as well as SiH₄ and H₂ gases, to thereby form the lightly doped P-type semiconductor layer 210. Subsequently, a supplying amount of B₂H₆ gas may be increased so as to form the highly doped P-type semiconductor layer 230. That is, even though the inside of the chamber is maintained in the P-type dopant atmosphere after manufacturing the initial solar cell, a very small amount of B₂H₆ gas may be supplied to the inside of the chamber so as to regulate the doping concentration of P-type impurity during the process for forming the lightly doped P-type semiconductor layer 210. Herein, the supplying amount of B₂H₆ gas is appropriately regulated to have such level as to prevent the occurrence of defect in the surface of the semiconductor wafer 100.

As explained above, since both the lightly doped P-type semiconductor layer 210 and the highly doped P-type semiconductor layer 230 can be sequentially formed in one chamber by regulating the supplying amount of reaction gases in one chamber, there is no requirement for the additional apparatus and process, thereby resulting in improvement of yield.

As shown in FIG. 3(B), the first transparent conductive layer 300 is formed on the first semiconductor layer 200.

A process for forming the first transparent conductive layer 300 may comprise depositing the transparent conductive material such as ZnO:B, ZnO:Al, SnO₂, SnO₂:F, or ITO (Indium Tin Oxide) by sputtering or MOCVD (Metal Organic Chemical Vapor Deposition). The first transparent conductive layer 300 may be omissible.

As shown in FIG. 3(C), the first electrode 400 is formed on the first transparent conductive layer 300.

The plurality of first electrodes 400 may be patterned at fixed intervals so that the solar ray can be transmitted to the inside of the solar cell through the interval between each first electrode 400.

A process for forming the first electrode 400 may comprise patterning the metal material such as Ag, Al, Ag+Al, Ag+Mg, Ag+Mn, Ag+Sb, Ag+Zn, Ag+Mo, Ag+Ni, Ag+Cu, or Ag+Al+Zn by sputtering; or may comprise directly patterning a paste of the aforementioned metal material by a screen-printing method, inkjet-printing method, gravure-printing method, or micro-contact printing method. This printing method enables to pattern the plurality of first electrodes 400 at fixed intervals by one process, thereby resulting in the simplified process.

As shown in FIG. 3(D), after inverting the semiconductor wafer 100, the second semiconductor layer 500 is formed on the semiconductor wafer 100.

A process for forming the second semiconductor layer 500 may comprise forming the N-type semiconductor layer, for example, the N-type amorphous silicon layer on the semiconductor wafer 100 by PECVD (Plasma Enhanced Chemical Vapor Deposition).

Another process for forming the second semiconductor layer 500 may comprise forming the lightly doped N-type semiconductor layer 510 on the semiconductor wafer 100; and forming the highly doped N-type semiconductor layer 530 on the lightly doped N-type semiconductor layer 510.

With similarity to the aforementioned lightly doped P-type semiconductor layer 210 and the highly doped P-type semiconductor layer 230, both the lightly doped N-type semiconductor layer 510 and the highly doped N-type semiconductor layer 530 can be sequentially formed in one chamber. That is, the lightly doped N-type semiconductor layer 510 and the highly doped N-type semiconductor layer 530 can be sequentially formed by regulating a supplying amount of dopant gas of group V element of the periodic table, for example, phosphorous (P) in a PECVD (Plasma Enhanced Chemical Vapor Deposition) chamber.

In more detail, after the N-type dopant atmosphere is created inside the chamber by supplying a predetermined amount of PH₃ gas to the inside of the chamber, SiH₄ and H₂ gases are supplied to the inside of the chamber, thereby forming the lightly doped N-type semiconductor layer 510. Thereafter, when supplying SiH₄ and H₂ gases, PH₃ gas serving as the dopant gas is additionally supplied to the inside of the chamber, thereby forming the highly doped N-type semiconductor layer 530.

With similarity to the aforementioned process for forming the P-type semiconductor layer 200, some of PH₃ gas may remain in the chamber after completing the process for forming the highly doped N-type semiconductor layer 530. From the process for manufacturing the following solar cells after the initial solar cell, the inside of the chamber is already prepared with the N-type dopant atmosphere. Thus, only SiH₄ and H₂ gases are supplied to the inside of the chamber without supplying the additional dopant gas of PH₃ gas to the inside of the chamber, to thereby form the lightly doped N-type semiconductor layer 510. Thereafter, when supplying SiH₄ and H₂ gases, PH₃ gas serving as the dopant gas is additionally supplied to the inside of the chamber, to thereby form the highly doped N-type semiconductor layer 530.

However, it is not limited to the aforementioned method. After manufacturing the initial solar cell, the chamber may be supplied with a very small amount of PH₃ gas as well as SiH₄ and H₂ gases, to thereby form the lightly doped N-type semiconductor layer 510. Thereafter, a supplying amount of PH₃ gas may be increased so as to form the highly doped N-type semiconductor layer 530.

As shown in FIG. 3(E), the second transparent conductive layer 600 is formed on the second semiconductor layer 500.

A process for forming the second transparent conductive layer 600 may comprise depositing the transparent conductive material such as ZnO:B, ZnO:Al, Sn0₂, Sn0₂:F, or ITO (Indium Tin Oxide) by sputtering or MOCVD (Metal Organic Chemical Vapor Deposition). The second transparent conductive layer 600 may be omissible.

As shown in FIG. 3(F), the second electrode 700 is formed on the second transparent conductive layer 600, thereby completing the hybrid solar cell according to the present invention.

A process for forming the second electrode 700 may comprise patterning the metal material such as Ag, Al, Ag+Al, Ag+Mg, Ag+Mn, Ag+Sb, Ag+Zn, Ag+Mo, Ag+Ni, Ag+Cu, or Ag+Al+Zn by sputtering; or may comprise directly patterning a paste of the aforementioned metal material by the aforementioned printing method.

According to the aforementioned methods, the first semiconductor layer 200, the first transparent conductive layer 300, and the first electrode 400 are sequentially formed on the upper surface of the semiconductor wafer 100; and the second semiconductor layer 500, the second transparent conductive layer 600, and the second electrode 700 are sequentially formed on the lower surface of the semiconductor wafer 100. However, the method for manufacturing the hybrid solar cell according to the present invention may have various modifications.

For example, one modified method for manufacturing the hybrid solar cell according to the present invention may comprise the sequential steps for forming the first semiconductor layer 200 and the first transparent conductive layer 300 on the upper surface of the semiconductor wafer 100; forming the second semiconductor layer 500 and the second transparent conductive layer 600 on the lower surface of the semiconductor wafer 100; forming the first electrode 400 on the first transparent conductive layer 300; and forming the second electrode 700 on the second transparent conductive layer 600. If needed, another modified method for manufacturing the hybrid solar cell according to the present invention may comprise the sequential steps for forming the first semiconductor layer 200 on the upper surface of the semiconductor wafer 100; forming the second semiconductor layer 500 on the lower surface of the semiconductor wafer 100; forming the first transparent conductive layer 300 on the first semiconductor layer 200; forming the second transparent conductive layer 600 on the second semiconductor layer 500; forming the first electrode 400 on the first transparent conductive layer 300; and forming the second electrode 700 on the second transparent conductive layer 600.

According to the aforementioned methods, the semiconductor wafer 100 is formed of the N-type semiconductor wafer; the first semiconductor layer 200 is formed of the P-type semiconductor layer; and the second semiconductor layer 500 is formed of the N-type semiconductor layer, but not necessarily. The aforementioned methods may have various modifications within the scope of maintaining the PN junction structure and the hybrid type comprising the semiconductor wafer and the thin film of semiconductor layer. For example, the semiconductor wafer 100 may be formed of the P-type semiconductor wafer; the first semiconductor layer 200 may be formed of the N-type semiconductor layer; and the second semiconductor layer 500 may be formed of the P-type semiconductor layer.

In the hybrid solar cell according to the present invention, the lightly doped semiconductor layer is firstly formed on the surface of the semiconductor wafer 100, and the highly doped semiconductor layer is then formed on the lightly doped semiconductor layer, thereby preventing the defect from occurring in the surface of the semiconductor wafer 100, and improving the cell efficiency by the increase of open-circuit voltage.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A hybrid solar cell comprising:
a semiconductor wafer having a predetermined polarity;
a first semiconductor layer on one surface of the semiconductor wafer, the first semiconductor layer comprising (i) a lightly doped first semiconductor layer on the one surface of the semiconductor wafer and (ii) a highly doped first semiconductor layer on the lightly doped first semiconductor layer;
a second semiconductor layer on another surface of the semiconductor wafer, wherein the second semiconductor layer has a polarity different from a polarity of the first semiconductor layer;
a first electrode on the first semiconductor layer; and
a second electrode on the second semiconductor layer.

2. The hybrid solar cell of claim 1, wherein the second semiconductor layer comprises:
a lightly doped second semiconductor layer on the other surface of the semiconductor wafer; and
a highly doped second semiconductor layer on the lightly doped second semiconductor layer.

3. The hybrid solar cell of claim 1, further comprising a first transparent conductive layer between the first semiconductor layer and the first electrode.

4. The hybrid solar cell of claim 1, further comprising a second transparent conductive layer between the second semiconductor layer and the second electrode.

5. The hybrid solar cell of claim 1, wherein the first electrode comprises a plurality of first electrodes, and the plurality of first electrodes are separated at fixed intervals sufficient to permit solar rays to pass therethrough.

6. The hybrid solar cell of claim 1, wherein the predetermined polarity of the semiconductor wafer and the polarity of the second semiconductor layer are the same.

7. The hybrid solar cell of claim 6, wherein:
the semiconductor wafer comprises an N-type semiconductor wafer;
the first semiconductor layer comprises a P-type semiconductor layer; and
the second semiconductor layer comprises an N-type semiconductor layer.

8. A method for manufacturing a hybrid solar cell comprising:
forming a first semiconductor layer on one surface of a semiconductor wafer having a predetermined polarity, wherein forming the first semiconductor layer comprises (i) forming a lightly doped first semiconductor layer on the one surface of the semiconductor wafer and (ii) forming a highly doped first semiconductor layer on the lightly doped first semiconductor layer; forming a second semiconductor layer on another surface of the semiconductor wafer, wherein the second semiconductor layer has a polarity different from a polarity of the first semiconductor layer;
forming a first electrode on the first semiconductor layer; and
forming a second electrode on the second semiconductor layer.

9. The method of claim 8, wherein forming the lightly doped first semiconductor layer and forming the highly doped first semiconductor layer are sequentially carried out in one chamber.

10. The method of claim 9, wherein:
forming the lightly doped first semiconductor layer is carried out without additionally supplying a predetermined dopant to the chamber prepared in a predetermined dopant atmosphere; and
forming the highly doped first semiconductor layer is carried out by additionally supplying the predetermined dopant to the chamber.

11. The method of claim 9, wherein forming the lightly doped first semiconductor layer comprises supplying a predetermined first amount of dopant to the chamber, and forming the highly doped first semiconductor layer comprises supplying a predetermined second amount of dopant to the chamber, wherein the predetermined second amount of dopant is larger than the predetermined first amount of dopant.

12. The method of claim 8, wherein forming the second semiconductor layer comprises:
forming a lightly doped second semiconductor layer on the other surface of the semiconductor wafer; and
forming a highly doped second semiconductor layer on the lightly doped second semiconductor layer.

13. The method of claim 12, wherein forming the lightly doped second semiconductor layer and forming the highly doped second semiconductor layer are sequentially carried out in one chamber.

14. The method of claim 8, further comprising forming a first transparent conductive layer between forming the first semiconductor layer and forming the first electrode.

15. The method of claim 8, further comprising forming a second transparent conductive layer between forming the second semiconductor layer and forming the second electrode.

16. The method of claim 8, wherein forming the first electrode comprises forming a plurality of first electrodes separated at fixed intervals sufficient to permit solar rays to pass therethrough.

17. The method of claim 8, wherein:
the first electrode is formed after forming the first semiconductor layer;
the second semiconductor layer is formed after forming the first electrode; and
the second electrode is formed after forming the second semiconductor layer.

18. The method of claim 8, wherein:
the semiconductor wafer comprises an N-type semiconductor wafer;
the first semiconductor layer comprises a P-type semiconductor layer; and
the second semiconductor layer comprises an N-type semiconductor layer.
